(19) United States
(12) Patent Application Publication
(10) Pub. No.: US 2025/0221153 A1
(43) Pub. Date: Jul. 3, 2025

(54) LIGHT EMITTING DEVICE AND LIGHT EMITTING DISPLAY DEVICE

(71) Applicant: LG DISPLAY CO., LTD., Seoul (KR)

(72) Inventors: Min Hyeong HWANG, Paju-si (KR); Eun Jung PARK, Paju-si (KR)

(73) Assignee: LG DISPLAY CO., LTD., Seoul (KR)

(21) Appl. No.: 18/919,903

(22) Filed: Oct. 18, 2024

(30) Foreign Application Priority Data
Dec. 29, 2023 (KR) 10-2023-0197864

(51) Int. Cl. H10K 50/13; H10K 50/19; H10K 59/38; H10K 102/00

(52) U.S. Cl. CPC H10K 50/131; H10K 50/19; H10K 59/38; H10K 2102/351

(57) ABSTRACT

A light emitting device includes a first electrode and a second electrode facing each other; and an intermediate layer structure having at least one blue stack and at least one phosphorescent stack disposed between the first electrode and the second electrode, wherein the at least one phosphorescent stack includes a first phosphorescent emission layer and a second phosphorescent emission layer in contact with each other between a hole transport layer and an electron transport layer, and wherein at least one of the first phosphorescent emission layer and the second phosphorescent emission layer includes charge control spots.

### CROSS-REFERENCE TO RELATED APPLICATION

This application claims the priority of Korean Patent Application No. 10-2023-0197864, filed on Dec. 29, 2023, which is hereby incorporated by reference in its entirety.

### BACKGROUND

### Field of the Disclosure

The present disclosure relates to a light emitting device, and more particularly to a light emitting device and a light emitting display device capable of improving both luminous efficacy and lifespan.

### Description of the Background

With the advent of the full-fledged information era, the display field that visually displays electrical information signals has developed rapidly, and accordingly, a variety of display devices with excellent performance such as slimness, light weight, and low power consumption are being developed.

Among such display devises, a light emitting display device configured such that there is no need for a separate light source, and a light emitting device provided in a display panel for compactness of the device and clear color display is considered as a competitive application.

A light emitting device may include an emission layer between two electrodes facing each other, and a common layer that transfers holes and electrons to the emission layer.

Also, a light emitting device may include a plurality of emission layers that emit light of different wavelengths for white display. When the emission layers are disposed adjacent to each other, there is a problem in that it is difficult to implement each emission layer to have optimal efficiency and lifespan.

### SUMMARY

Accordingly, the present disclosure is directed to a light emitting device and a light emitting display device that substantially obviate one or more of problems due to limitations and disadvantages described above.

More specifically, the present disclosure is to provide a light emitting device including a material capable of controlling charges in an emission layer and a light emitting display device including the same.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a light emitting device includes a first electrode and a second electrode facing each other; and an intermediate layer structure having at least one blue stack and at least one phosphorescent stack disposed between the first electrode and the second electrode, wherein the at least one phosphorescent stack includes a first phosphorescent emission layer and a second phosphorescent emission layer in contact with each other between a hole transport layer and an electron transport layer, and wherein at least one of the first phosphorescent emission layer and the second phosphorescent emission layer includes charge control spots.

In another aspect of the present disclosure, a light emitting display device includes a substrate comprising a plurality of sub-pixels; a thin film transistor provided in each of the plurality of sub-pixels; and a light emitting device connected to the thin film transistor in each of the plurality of sub-pixels, the light emitting device comprising an intermediate layer structure having at least one blue stack and at least one phosphorescent stack between a first electrode and a second electrode, wherein the at least one phosphorescent stack comprises a first phosphorescent emission layer and a second phosphorescent emission layer in contact with each other between a hole transport layer and an electron transport layer, at least one of the first phosphorescent emission layer and the second phosphorescent emission layer comprises charge control spots.

In a further aspect of the present disclosure, a light emitting diode includes first and second blue stacks configured to emit a blue wavelength; a phosphorescent stack disposed between the first and second blue stacks and including a hole transport layer, an electron transport layer, a first phosphorescent emission layer emitting a first color wavelength and a second phosphorescent emission layer emitting a second color wavelength, wherein the first and second phosphorescent emission layers are disposed between the hole transport layer and the electron transport layer; and at least one charge control layer disposed in at least one of the first phosphorescent emission layers emission layer and the second phosphorescent emission layer, wherein the at least one charge control layer includes a plurality of charge control spots disposed on a same plane and separated apart from one another.

In various aspects of the present disclosure, plate-like charge control spots may be dispersed in a structure in which phosphorescent emission layers are in contact, thus controlling the speed of charges including holes and electrons by the structure and properties of the plate-like charge control spots and preventing charges from accumulating at the interface of the emission layers, thereby improving both efficiency and lifespan.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate various aspects of the present disclosure and together with the description serve to explain the principle of the disclosure.

In the drawings:

FIG. 1 is a cross-sectional view showing a light emitting device according to an aspect of the present disclosure;

FIG. 2 shows a stack configuration in which the interfaces of layers are oriented perpendicular to the surface of a first electrode in one aspect of a phosphorescent stack of FIG. 1;

FIG. 3 three-dimensionally shows a green emission layer of FIG. 1;

FIG. 4 shows a phosphorescent stack according to the first experimental example;

FIG. 5 shows phosphorescent stacks according to the second to fifth experimental examples;

FIG. 6 shows phosphorescent stacks according to the sixth to eighth experimental examples;

FIG. 7 is a graph showing a change in luminance over time in the first to fifth experimental examples;

FIG. 8 is a graph showing a change in luminance over time in the first experimental example and the sixth to eighth experimental examples;

FIG. 9 shows a phosphorescent stack used in the second experiment;

FIG. 10 is a graph showing a change in luminance over time depending on the thickness of a charge control layer; and

FIG. 11 is a cross-sectional view showing a light emitting display device according to an aspect of the present disclosure.

### DETAILED DESCRIPTION

Reference will now be made in detail to example aspects of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example aspects described herein in detail together with the accompanying drawings. The present disclosure should not be construed as limited to the example aspects as disclosed below, and may be embodied in various different forms. Thus, these example aspects are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations may unnecessarily obscure an important point of the present disclosure, a detailed description of such steps, elements, functions, technologies, and configurations maybe omitted. In addition, the names of elements used in the following description are selected in consideration of clarity of description of the specification, and may differ from the names of elements of actual products. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example aspects of the present disclosure are merely given by way of example. The disclosure is not limited to the illustrations in the drawings.

In the present specification, where terms such as “including,” “having,” “comprising,” and the like are used, one or more components may be added, unless the term, such as “only,” is used. As used herein, the term “and/or” includes a single associated listed item and any and all of the combinations of two or more of the associated listed items.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example aspects of the present disclosure, where the positional relationship between two elements is described using terms, such as “on”, “above”, “under” and “next to”, at least one intervening element may be present between the two elements, unless “immediate(ly)” or “direct(ly)” or “close(ly) is used. It will be understood that when an element or layer is referred to as being “connected to”, or “coupled to” another element or layer, it may be directly connected to or coupled to the other element or layer, or one or more intervening elements or layers may be present.

In describing the various example aspects of the present disclosure, when terms such as “after,” “subsequently,” “next,” and “before,” are used to describe the temporal relationship between two events, another event may occur therebetween, unless a more limiting term, such as “just,” “immediate(ly),” or “directly” is used.

In describing the various example aspects of the present disclosure, terms such as “first” and “second” may be used to describe a variety of components. These terms aim to distinguish the same or similar components from one another and do not limit the components. Accordingly, throughout the specification, a “first” component may be the same as a “second” component within the technical concept of the present disclosure, unless specifically mentioned otherwise.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

In the following description of the present disclosure, the Lowest Unoccupied Molecular Orbital (LUMO) energy level and the Highest Occupied Molecular Orbital (HOMO) energy level of a layer mean the LUMO energy level and the HOMO energy level of a material constituting a major weight ratio of the corresponding layer, unless they refer to the LUMO energy level and the HOMO energy level of a dopant material doping the corresponding layer.

In the following description of the present disclosure, a HOMO energy level may be obtained by measuring a voltage corresponding to a first peak at which electrons pop out from material through cyclic voltammetry (CV) for the material to be measured, compared to a reference material whose HOMO energy level is known. Herein, the electron that first comes out of the material is the weakest bound electron, the outermost electron, and is in the state of the HOMO energy level.

In the present disclosure, a band gap energy (Eg) may be measured by ultraviolet-visible spectrometry (UVvis).

In the present disclosure, a LUMO energy level may be obtained by subtracting the band gap energy from the HOMO energy level measured above.

In the present disclosure, the HOMO energy level and the LUMO energy level are measured values below the vacuum level of 0 eV, thus they are negative values. When the HOMO energy levels or LUMO energy levels of materials are compared, that the HOMO energy level (or the LUMO energy level) of a first material is larger than the HOMO energy level (or the LUMO energy level) of a second material in an energy band diagram means that the HOMO energy level (or the LUMO energy level) of the second material is larger than the HOMO energy level (or the LUMO energy level) of the first material in absolute values. When the HOMO energy levels or LUMO energy levels of materials are compared, that the HOMO energy level (or the LUMO energy level) of a first material is lower than the HOMO energy level (or the LUMO energy level) of a second material in an energy band diagram means that the HOMO energy level (or the LUMO energy level) of the first material is larger than the HOMO energy level (or the LUMO energy level) of the second material in an absolute value.

As used herein, the term “doped” layer refers to a layer including a first material and a second material (for example, n-type and p-type materials, or organic and inorganic substances) having physical properties different from the first material. Apart from the differences in properties, the first and second materials may also differ in terms of their amounts in the doped layer. For example, the host material may be a major component while the dopant material may be a minor component. The first material accounts for most of the weight of the doped layer. The second material may be added in an amount less than 30% by weight, based on a total weight of the first material in the doped layer. A “doped” layer may be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Also, the term “undoped” refers to layers that are not “doped”. For example, a layer may be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum may be calculated by multiplying (a) a photoluminescence (PL) spectrum, which applies the inherent characteristics of an emissive material such as a dopant material or a host material included in an organic emission layer, by (b) an out-coupling or emittance spectrum curve, which is determined by the structure and optical characteristics of an organic light-emitting element including the thicknesses of organic layers such as, for example, an electron transport layer.

Hereinafter, example aspects of the present disclosure will be described in detail with reference to the accompanying drawings. In adding reference numerals to elements of each of the drawings, although the same elements are illustrated in other drawings, like reference numerals may refer to like elements. Also, for convenience of description, a scale in which each of elements is illustrated in the accompanying drawings may differ from an actual scale. Thus, the illustrated elements are not limited to the specific scale in which they are illustrated in the drawings.

Hereinafter, a detailed description will be given of aspects of the present disclosure with reference to the accompanying drawings.

As used herein, the term “stack” refers to a unit structure including a common layer including a hole transport layer and an electron transport layer, and an emission layer disposed between the hole transport layer and the electron transport layer, unless limited to a specific structure in aspects. The common layer may further include a hole injection layer, an electron blocking layer, a hole blocking layer, and an electron injection layer, and may additionally include other common layers depending on the structure or design of the light emitting device. The common layer may include an organic layer, an inorganic layer, or an organic material and an inorganic material.

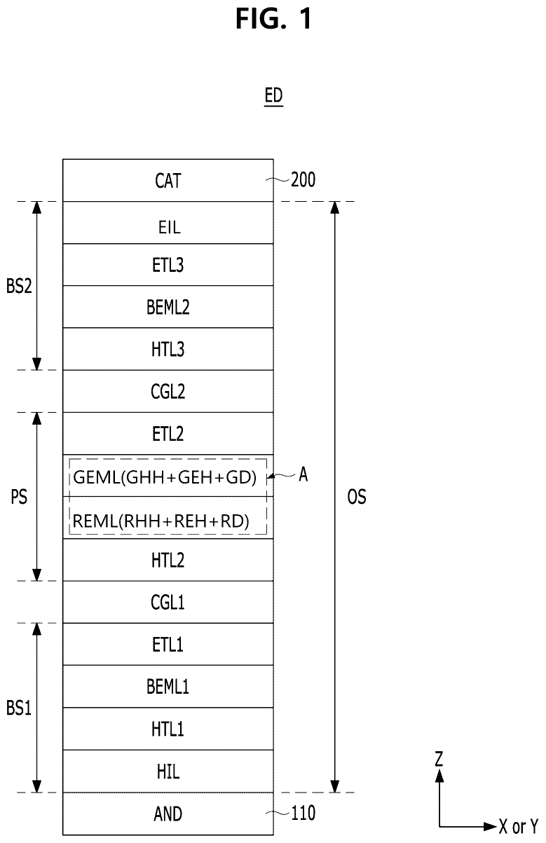

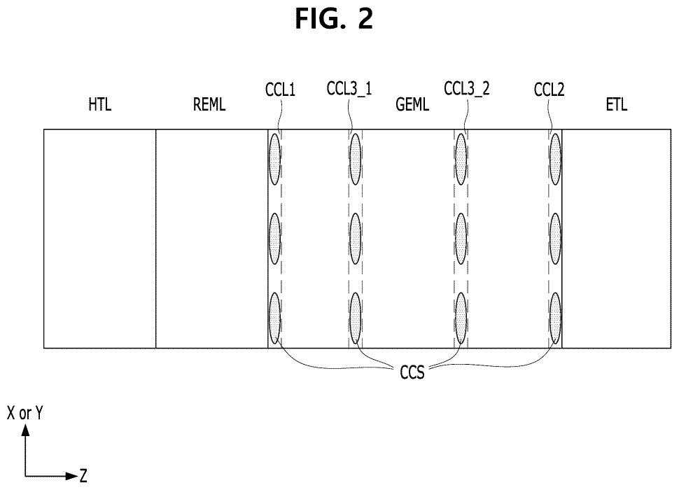

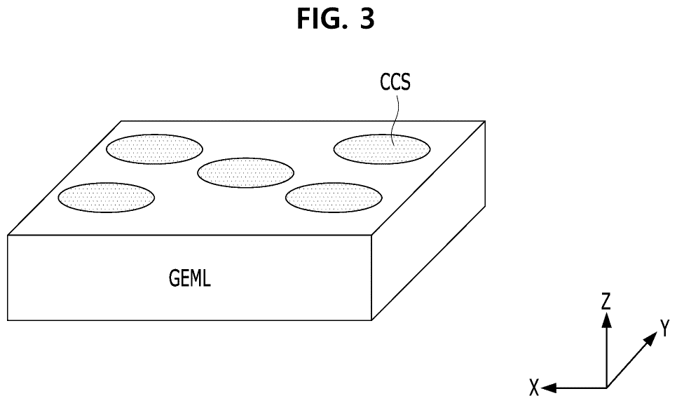

FIG. 1 is a cross-sectional view showing a light emitting device according to an aspect of the present disclosure. FIG. 2 shows the interfaces of layers in a direction perpendicular to the surface of the first electrode in one aspect of the phosphorescent stack of FIG. 1. FIG. 3 three-dimensionally shows the green emission layer of FIG. 1.

As shown in FIG. 1, the light emitting device ED according to an aspect of the present disclosure includes a first electrode 110 and a second electrode 200 facing each other, and an intermediate layer structure OS (or a resultant color emitting stack) configured to include at least one blue stack BS1, BS2 and at least one phosphorescent stack PS between the first electrode 110 and the second electrode 200 and to emit white light as a resultant color.

One of the first electrode 110 and the second electrode 200 may be an anode AND, and the remaining one may be a cathode CAT. FIG. 1 shows an example in which the first electrode 110 is an anode and the second electrode 200 is a cathode, but the aspect of the present disclosure is not limited thereto.

One of the first electrode 110 and the second electrodes 200 may be connected to the thin film transistor of each sub-pixel provided on a substrate, and the remaining one may be formed integrally and may receive a common voltage from a plurality of sub-pixels.

One of the first electrode 110 and the second electrode 200 may be a reflective electrode, and the remaining one may be a transparent electrode or a semi-transparent electrode. When the first electrode 110 is a transparent electrode and the second electrode 200 is a reflective electrode, a bottom-emission light emitting device may be realized. When the first electrode 110 is a reflective electrode and the second electrode 200 is a transparent electrode or a semi-transparent electrode, a top-emission light emitting device may be realized. In another aspect of the present disclosure, when each of the first electrode 110 and the second electrode 200 is a non-reflective electrode, a dual-emission light emitting device may be realized.

When the first electrode 110 is a transparent electrode, the first electrode 110 may include one of ITO (indium tin oxide), IZO (indium zinc oxide), and ITZO (indium tin zinc oxide). When the second electrode 200 is a reflective electrode, the second electrode 200 may include aluminum (Al), silver (Ag), magnesium (Mg), or an alloy containing any one thereof.

At least one of the first electrode 110 or the second electrode 200 may include a plurality of layers.

The first electrode 110 is connected to a thin film transistor provided on the substrate to selectively receive a signal supplied to each sub-pixel, and the second electrode 200 is provided in common to the sub-pixels to receive a common voltage. The light emitting device according to the aspect of the present disclosure is not limited to FIG. 1. For example, the configuration of the light emitting device ED in FIG. 1 may be inverted upside down so that the second electrode 200 located at the lower side is connected to a thin film transistor and the first electrode located at the upper side is provided across a plurality of sub-pixels to receive a common voltage.

An intermediate layer structure OS is provided between the first and second electrodes 110, 200, and the emission characteristics of the light emitting device may be controlled depending on the thickness of the intermediate layer structure OS and the layers included in the intermediate layer structure OS. The intermediate layer structure OS may include a plurality of organic layers. Some of the layers included in the intermediate layer structure OS may further include a metal or an inorganic material other than the metal. The metal and the inorganic material other than the metal may be provided alone in some of the layers, or may form a complex with an organic material.

For example, the intermediate layer structure OS may include multiple stacks BS1, PS, BS2 to emit white light. As shown, the number of provided stacks BS1, PS, BS2 may be 3, but the aspect of the present disclosure is not limited thereto. The number of stacks provided in the intermediate layer structure OS may be 2 or 4, or more. A charge generation layer CGL1, CGL2 is provided between the stacks to generate and transfer holes or electrons required for each stack. For example, the charge generation layer CGL1, CGL2 may be composed of a plurality of layers, including an n-type charge generation layer and a p-type charge generation layer, respectively, containing an n-type dopant and a p-type dopant. The present disclosure is not limited thereto, and the charge generation layer CGL1, CGL2 may be formed as a single layer, or at least one of the n-type charge generation layer or the p-type charge generation layer may be formed as a plurality of layers with different amounts of components. Some of two or more charge generation layers CGL1, CGL2 provided in three or more stacks may have different layer configurations, as necessary.

The first blue stack BS1 may include a hole injection layer HIL disposed adjacent to the first electrode 110 and configured to inject holes from the first electrode 110, a first hole transport layer HTL1 configured to transport holes from the hole injection layer HIL 121, a first blue emission layer BEML1, and a first electron transport layer ETL1.

The second blue stack BS2 may include a third hole transport layer HTL3, a second blue emission layer BEML2, a third electron transport layer ETL3, and an electron injection layer EIL adjacent to the second electrode 200.

The phosphorescent stack PS may include a second hole transport layer HTL2, a plurality of phosphorescent emission layers A, and a second electron transport layer ETL2. The phosphorescent emission layers A may be formed, for example, by stacking a red emission layer REML and a green emission layer GEML. The phosphorescent emission layers A are not limited to a two-layer configuration. For example, when the number of phosphorescent emission layers A is three or more, the phosphorescent emission layers A may be configured such that an emission layer with the longest wavelength is disposed on the side closest to the first electrode 110, and emission layers with gradually shorter wavelengths moving away from the first electrode 110 are disposed. For example, a red emission layer REML, followed by a yellow-green emission layer YGEML and a green emission layer GEML, may be disposed in that order on the side close to the first electrode 110.

The phosphorescent emission layers A may be adjusted for the number and emission color of phosphorescent emission layers included therein depending on the color temperature or luminance characteristics required by the light emitting display device. For example, to increase the luminance of pure color and improve color reproducibility, the phosphorescent emission layers A may have a stack configuration of pure red and green emission layers, in which the red emission layer REML and the green emission layer GEML may be configured to be in contact with each other.

Here, the red emission layer REML includes a hole transport host RHH, an electron transport host REH, and a red dopant RD.

The green emission layer GEML includes a hole transport host GHH, an electron transport host GEH, and a green dopant GD.

The red emission layer REML and the green emission layer GEML in the phosphorescent emission layers A are disposed between the second hole transport layer HTL2 that transfers holes and the second electron transport layer ETL2 that transfers electrons. Holes are supplied from the second hole transport layer HTL2 on one side of the red emission layer REML, and electrons are supplied from the second electron transport layer ETL2 on one side of the green emission layer GEML, so that holes and electrons are shared and transferred to the red emission layer REML and the green emission layer GEML. Accordingly, excitons formed by recombination of holes and electrons are distributed in the red emission layer REML and the green emission layer GEML.

The red emission layer REML and the green emission layer GEML may have different hole transport host-to-electron transport host ratios (RHH:REH/GHH:GEH), controlling the location of the emission region and exciton distribution. Specifically, by adjusting the hole transport host-to-electron transport host ratio (RHH:REH/GHH:GEH), the maximum intensity of exciton generation is at the interface between the red emission layer REML and the green emission layer GEML, so that charge distribution may be controlled in the phosphorescent emission layers A. However, if excitons are intensively generated at the interface between the red emission layer REML and the green emission layer GEML, charges such as excitons, etc. may accumulate at the interface between the red emission layer REML and the green emission layer GEML. Charges accumulated at the interface are not used for light emission in either the red emission layer REML or the green emission layer GEML, which may cause the efficiency of each emission layer to decrease. Moreover, device deterioration and shortened lifespan may be caused by the charges accumulated at the interface between the red emission layer REML and the green emission layer GEML.

Meanwhile, when the light emitting device ED emits white light, the green emission layer GEML, which has relatively high white contribution efficiency, may be formed to be thicker than the red emission layer REML. In this case, when excitons are distributed in the red emission layer REML and the green emission layer GEML, the excitons may be biased at the interface between the red emission layer REML and the green emission layer GEML, and thus there may be a large variation in efficiency and lifespan of the device. To prevent this problem, partial separation may be achieved by inserting a thin separation layer into the interface between the red emission layer REML and the green emission layer GEML. However, when a separation layer is provided in the phosphorescent emission layers A, the exciton density of the red emission layer REML, which is thinner than the green emission layer GEML, is high, so the green emission intensity may be lowered and the red emission intensity may be increased. Hence, it is difficult to improve both efficiency and lifespan in the phosphorescent emission layers A simply by inserting a separation layer.

The light emitting device according to an aspect of the present disclosure is characterized by dispersing charge control spots CCS capable of controlling charges in a relatively thick phosphorescent emission layer.

Below is a description of an improvement in efficiency and lifespan by including charge control spots in the green emission layer GEML.

As shown in FIG. 3, charge control spots CCS have a plate-like structure, and may be disposed with a long axis along the surface (XY plane) of the green emission layer GEML and a short axis in the thickness direction (Z-axis) of the green emission layer GEML. As shown in FIG. 3, since charge control spots CCS have a plate-like structure, they are spaced apart from each other and arranged in islands. Therefore, the space between the charge control spots CCS is filled with the hosts GHH, GEH as main components of the green emission layer GEML, and a small amount of green dopant GD is added to the mixed host. The charge control spots CCS may not interfere with the flow of charges through the hosts, but may transfer energy required for triplet exciton formation to the green dopant GD, helping form triplet excitons in the green dopant GD, and the charge control spots CCS may be distributed in the green emission layer GEML, controlling the flow of charges, including triplet excitons.

As shown in FIG. 2, the charge control spots CCS may have a layered arrangement of one or more charge control layers CCL1, CCL2, CCL3_1, CCL2 parallel to the interface between the red emission layer REML and the green emission layer GEML.

The interface between the red emission layer REML and the green emission layer GEML is a two-dimensional plane parallel to the surface of the substrate, which is the formation surface of the light emitting device. In FIGS. 2 and 3, the two-dimensional plane indicates a two-dimensional plane including the X and Y axes where the interface between the red emission layer REML and the green emission layer GEML is located. The Z axis shown in FIGS. 2 and 3 indicates a thickness direction in which the red emission layer REML and the green emission layer GEML are stacked in the light emitting device ED.

As shown in FIG. 2, when a plurality of charge control layers CCL1, CCL2, CCL3_1, CCL3_2 is provided in the green emission layer GEML, the charge control layers CCL1, CCL2, CCL3_1, CCL3_2 are spaced apart from one another in the thickness direction for island arrangement through structural separation with a gap therebetween. Here, the charge control layers CCL1, CCL2, CCL3_1, CCL3_2 each independently have a thickness of about 15 Å to 65 Å, for example 30 Å to 50 Å for the advantage of energy transfer to the green dopant GD and uniformity in the green emission layer GEML.

FIG. 2 shows an example in which the charge control spots CCS in the green emission layer GEML include all of a first charge control layer CCL1 provided in contact with the interface between the red emission layer REML and the green emission layer GEML, a second charge control layer CCL2 provided in contact with the interface between the green emission layer GEML and the electron transport layer ETL, and third charge control layers CCL3_1, CCL3_2 provided in the green emission layer GEML while being spaced apart from each of the red emission layer REML and the electron transport layer ETL.

The first to third charge control layers CCL1, CCL2, CCL3_1, CCL3_2 are all arranged parallel to the interface between the green emission layer GEML and the red emission layer REML and have a layered configuration or structure.

In addition, FIG. 2 shows a structure in which two third charge control layers CCL3_1, CCL3_2 are spaced apart from each other in the green emission layer GEML.

However, the light emitting device according to the aspect of the present disclosure is not limited to the example of FIG. 2. Specifically, arrangement of the charge control spots CCS in the green emission layer GEML is effective at controlling the flow of charges and improving lifespan even when at least one of the first to third charge control layers CCL1, CCL2, CCL3_1, CCL3_2 is provided, which will be described later through experiments.

As shown in FIGS. 2 and 3, the charge control spots have the advantage of being able to be arranged in layers with space therebetween due to the shape of the physical plate-like structure, and have the following differences from the host and dopant, which are physically adjacent materials, making it possible to control the flow of holes and electrons and transfer energy to help form triplet excitons in the dopant.

The HOMO energy level of the charge control spots CCS is lower than the HOMO energy level of the hole transport host GHH included in the green emission layer GEML, facilitating injection of holes to the hole transport host in the green emission layer through the charge control spots CCS.

Also, the LUMO energy level of the charge control spots CCS is higher than the LUMO energy level of the electron transport host GEH included in the green emission layer GEML, facilitating injection of electrons to the electron transport host GEH in the green emission layer GEH through the charge control spots CCS.

In addition, the triplet energy level (T1) of the charge control spots CCS is greater than the triplet energy level of the green dopant GD, facilitating transfer of energy to the green dopant GD.

Specifically, the HOMO energy level of the charge control spots CCS may be lower than the HOMO energy level of the hole transport host GHH included in the green emission layer GEML and the LUMO energy level thereof be higher than the LUMO energy level of the electron transport host included in the green emission layer GEML. However, the HOMO energy level difference between the charge control spots CCS and the adjacent hole transport host GHH has not to exceed 0.3 eV to prevent hole trapping due thereto, and the LUMO energy level difference between the charge control spots CCS and the adjacent electron transport host GEH has not to exceed 0.3 eV to prevent electron trapping due thereto. Additionally, the triplet energy level (T1) of the charge control spots CCS is greater than the triplet energy level of the green dopant GD. By virtue of these properties of the charge control spots, both expanding light emission distribution in the green emission layer GEML through hole injection and lowering device operating voltage through electron injection may be obtained. Moreover, the charge control spots CCS have a triplet energy level higher than the triplet energy level of the green dopant GD, which may help improve luminous efficacy due to formation of excitons in the green dopant GD.

The charge control spots CCS having the properties described above may include, as a material having a plate-like structure, a bipolar organic material containing both a group with strong hole transport and a group with strong electron transport. An example of the charge control spots CCS may be a compound containing an indolocarbazole group with strong hole transport and a triazine group with strong electron transport.

To ensure the properties of the charge control spots CCS described above and the layered arrangement in islands, the thickness of the layered structure may be about 15 Å to 65 Å, for example 30 Å to 50 Å for the advantage of energy transfer to the green dopant GD and uniformity in the green emission layer GEML.

In the following experiment, the material of [Chemical Formula 1] was used as an example of the charge control spots. The bipolar material used in the experiment satisfies the properties described above, and may be changed to another material so long as it satisfies the properties described above.

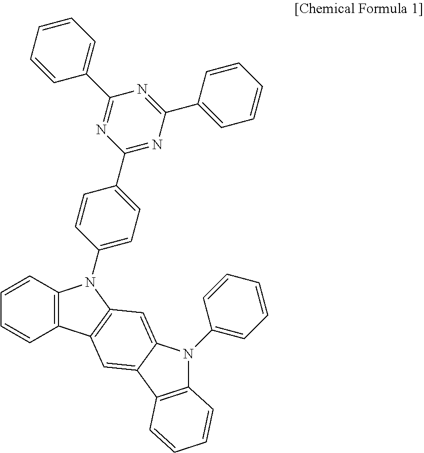 [SMILES: c1ccc(-c2nc(-c3ccccc3)nc(-c3ccc(-n4c5ccccc5c5cc6c7ccccc7n(-c7ccccc7)c6cc54)cc3)n2)cc1]

The hole transport host GHH, the electron transport host GEH, the green dopant, and the charge control spots CCS of Chemical Formula 1 included in the green emission layer GEML have the properties shown in Table 1 below.

TABLE 1

| | HOMO | LUMO | T1 |
|---|---|---|---|
| Material | [eV] | [eV] | [eV] |
| GHH | −5.37 | −1.97 | 2.75 |
| GEH | −5.99 | −2.86 | 2.73 |
| GD | −5.05 | −2.65 | 2.40 |
| CCS | −5.51 | −2.70 | 2.65 |

Also, the properties of the hole transport host RHH, the electron transport host REH, and the red dopant RD included in the red emission layer REML adjacent to the green emission layer GEML used in the following experiment, and of the hole transport layer HTL adjacent to the red emission layer REML and the electron transport layer ETL adjacent to the green emission layer GEML are as follows.

TABLE 2

| | | | HOMO | LUMO | T1 |
|---|---|---|---|---|---|
| | Material | | [eV] | [eV] | [eV] |
| HTL | | | −5.55 | −2.42 | 2.62 |
| | REML | RHH | −5.50 | −2.42 | 2.62 |
| | | REH | −5.57 | −2.82 | 2.37 |
| | | RD | −5.00 | −3.10 | 2.10 |

| | | | |
|---|---|---|---|
| ETL | −5.30 | −2.15 | 1.73 |

The properties of the hole transport layer, the red emission layer, and the electron transport layer shown in Table 2 are exemplary and may be changed so long as they do not restrict the flow of holes and electrons.

### First Experiment

Below is a description of the effects depending on the number and arrangement of charge control layers formed using charge control spots through the first experiment. There are provided the first to eighth experimental examples in which the number of charge control layers formed and the arrangement of the charge control layers are varied.

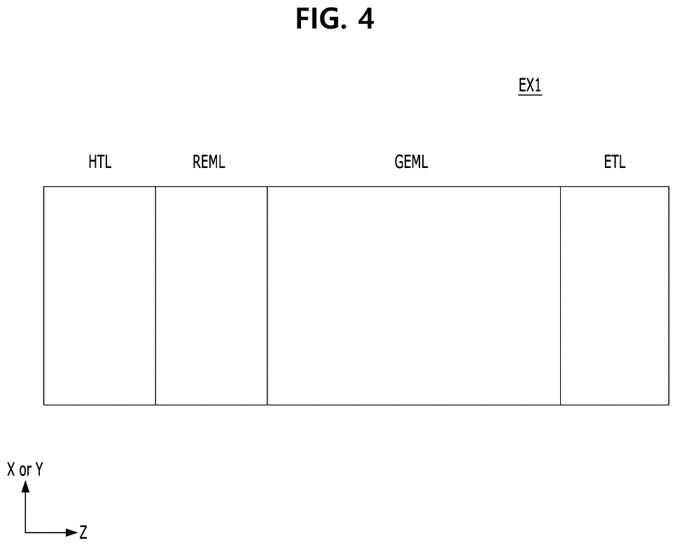

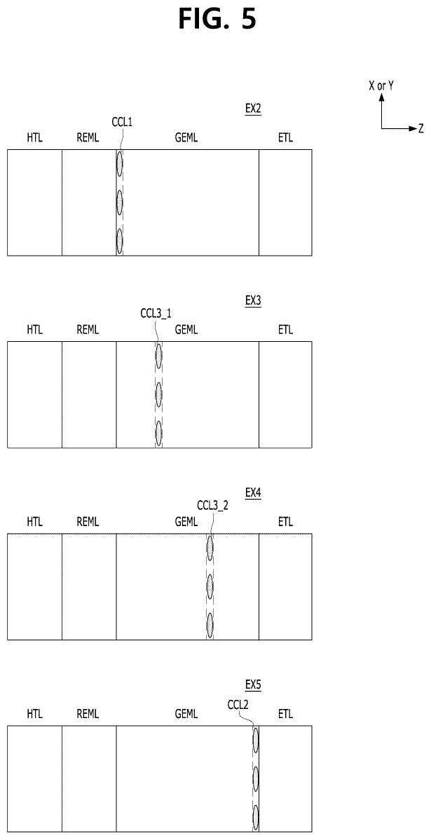

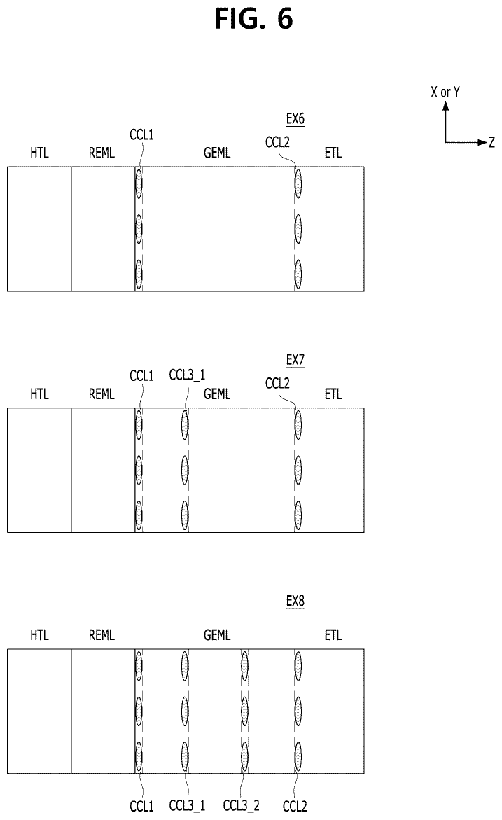

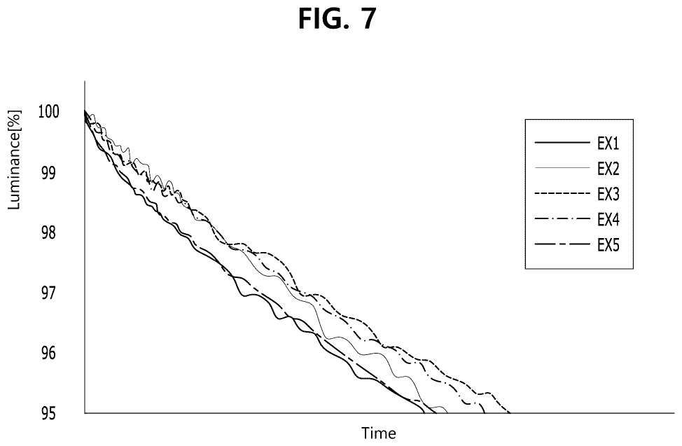

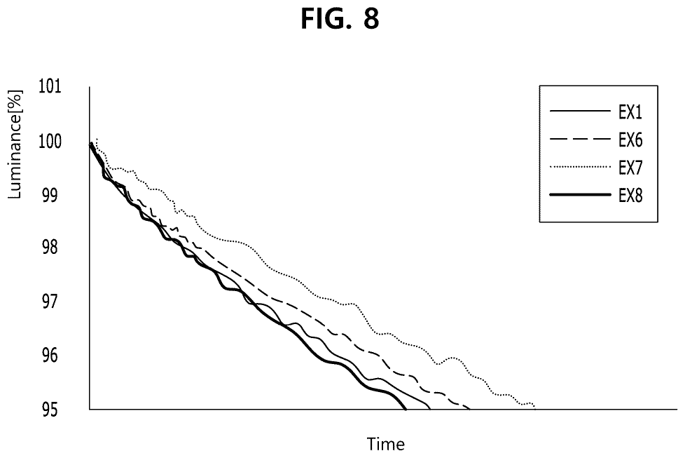

FIG. 4 shows a phosphorescent stack according to the first experimental example. FIG. 5 shows phosphorescent stacks according to the second to fifth experimental examples. FIG. 6 shows phosphorescent stacks according to the sixth to eighth experimental examples. FIG. 7 is a graph showing a change in luminance over time in the first to fifth experimental examples. FIG. 8 is a graph showing a change in luminance over time in the first experimental example and the sixth to eighth experimental examples.

The light emitting devices of the first to eighth experimental examples EX1-EX8 were configured such that the phosphorescent stack PS of FIG. 1 was provided between the anode AND and the cathode CAT, and there were differences in the presence or absence of charge control spots CCS in only the green emission layer GEML and the arrangement and number of charge control layers CCL.

Referring to FIGS. 4 and 1, the light emitting device according to the first experimental example EX1 applied in the first experiment has the following structure.

An anode AND including ITO is provided on a substrate.

A hole injection layer HIL is provided on the anode (AND).

A hole transport layer HTL is provided on the hole injection layer HIL.

A red emission layer REML including a hole transport host RHH, an electron transport host RGH, and a red dopant RD is provided at a thickness of 150 Å on the hole transport layer HTL. The ratio of hole transport host RHH to electron transport host REH in the red emission layer REML was 4:6, and the red dopant RD was doped in an amount of 2 wt % based on the total amount of the mixed host.

A green emission layer GEML including a hole transport host GHH, an electron transport host GEH, and a green dopant GD is provided at a thickness of 350 Å on the red emission layer REML. The ratio of hole transport host GHH to electron transport host GEH in the green emission layer GEML was 6:4, and the green dopant GD was doped in an amount of 15 wt % based on the total amount of the mixed host.

An electron transport layer ETL is provided on the green emission layer GEML.

An electron injection layer EIL is provided on the electron transport layer ETL.

A cathode CAT is formed of aluminum (Al) on the electron injection layer EIL, thereby completing the light emitting device according to the first experimental example EX1.

As shown in FIG. 5, the second experimental example EX2 has the same configuration as in the first experimental example EX1, with the exception that a first charge control layer CCL1 including charge control spots is further provided at the interface between the red emission layer REML and the green emission layer GEML.

Specifically, in the second experimental example EX2, in the initial stage of forming the green emission layer GEML, charge control spots CCS are supplied to form a thickness of 30 Å from the upper surface of the red emission layer REML. Thereafter, when a hole transport host GHH, an electron transport host GEH, and a green dopant GD are deposited, the space between the charge control spots CCS spaced apart in islands is filled therewith, thereby forming a green emission layer GEML including the hole transport host GHH, the electron transport host GEH, and the green dopant GD and having the same thickness as in the first experimental example EX1.

In the third experimental example EX3, materials including a hole transport host GHH, an electron transport host GEH, and a green dopant GD are first deposited to a thickness of 100 Å from the upper surface of the red emission layer REML, after which charge control spots CCS are supplied to a thickness of 30 Å, forming a third charge control layer CCL3_1 at a position spaced apart by a vertical distance of 100 Å from the upper surface of the red emission layer REML. Next, materials including the hole transport host GHH, the electron transport host GEH, and the green dopant GD are deposited again, thereby forming a green emission layer GEML at the same thickness as in the first experimental example EX1.

In the fourth experimental example EX4, materials including a hole transport host GHH, an electron transport host GEH, and a green dopant GD are first deposited to a thickness of 210 Å from the upper surface of the red emission layer REML, after which charge control spots CCS are supplied to a thickness of 30 Å, forming a third charge control layer CCL3_2 at a position spaced apart by a vertical distance of 210 Å from the upper surface of the red emission layer REML. Next, materials including the hole transport host GHH, the electron transport host GEH, and the green dopant GD are deposited again, thereby forming a green emission layer GEML at the same thickness as in the first experimental example EX1.

In the fifth experimental example EX5, materials including a hole transport host GHH, an electron transport host GEH, and a green dopant GD are first deposited to a thickness of 320 Å from the upper surface of the red emission layer REML, after which, in the final deposition process at a thickness of 30 Å, charge control spots CCS are supplied together with materials including the hole transport host GHH, the electron transport host GEH, and the green dopant GD, forming a second charge control layer CCL2 in a layered structure. Since the electron transport layer ETL is formed immediately after formation of the second charge control layer CCL2, the second charge control layer CCL2 is disposed at the interface between the green emission layer GEML and the electron transport layer ETL.

As shown in FIG. 6, in the sixth experimental example EX6, a first charge control layer CCL1 is formed at the interface between the red emission layer REML and the green emission layer GEML, and a second charge control layer CCL2 is formed at the interface between the green emission layer GEML and the electron transport layer ETL. The thickness of each of the first and second charge control layers CCL1, CCL2 was 30 Å.

The seventh experimental example EX7 has the same configuration as in the sixth experimental example EX6, with the exception of further providing a third charge control layer CCL3_1 spaced apart from each of the red emission layer REML and the electron transport layer ETL in the green emission layer GEML, with a shorter separation distance from the red emission layer REML. The thickness of each of the first charge control layer CCL1, the second charge control layer CCL2, and the third charge control layer CCL3_1 was 30 Å.

The eighth experimental example EX8 is configured to include, as described in FIG. 2, a first charge control layer CCL1 provided in contact with the interface between the red emission layer REML and the green emission layer GEML, a second charge control layer CCL2 provided in contact with the interface between the green emission layer GEML and the electron transport layer ETL, and a plurality of third charge control layers CCL3_1, CCL3_2 provided in the green emission layer GEML while being spaced apart from each of the red emission layer REML and the electron transport layer ETL. The thickness of each of the first charge control layer CCL1, the second charge control layer CCL2, and the third charge control layers CCL3_1, CCL3_2 was 30 Å.

In Table 3 below, lifespan (T95) indicates the time until the luminance reaches 95% of initial luminance. The lifespan was tested under acceleration conditions of high temperature and high current density, which was conducted under harsher conditions than normal operation.

TABLE 3

| | Operating | | | |
|---|---|---|---|---|
| | voltage [V] | Efficiency | EQE | Lifespan |
| Classification | (at 10J) | (%) | (%) | (T95, %) |
| EX1 | 4.0 | 100 | 100 | 100 |
| EX2 | 3.9 | 107 | 107 | 107 |
| EX3 | 4.0 | 103 | 103 | 125 |
| EX4 | 4.0 | 97 | 101 | 118 |
| EX5 | 3.9 | 98 | 105 | 108 |

TABLE 4

| | Operating | | | |
|---|---|---|---|---|
| | voltage [V] | Efficiency | EQE | Lifespan |
| Classification | (at 10J) | (%) | (%) | (T95, %) |
| EX1 | 4.0 | 100 | 100 | 100 |
| EX6 | 3.8 | 91 | 95 | 114 |
| EX7 | 4.0 | 87 | 88 | 132 |
| EX8 | 4.0 | 91 | 96 | 93 |

The efficiency and lifespan of the light emitting device are determined by distribution of formed excitons in the phosphorescent emission layers A (FIG. 1).

In a structure where the red emission layer REML and the green emission layer GEML are continuously stacked and are in contact with each other, the amount of excitons generated is the greatest at the interface between the red emission layer REML and the green emission layer GEML, and tends to decrease toward the adjacent common layers HTL, ETL. To alleviate accumulation at the interface of the emission layers where the concentration of excitons is the highest, the second to eighth experimental examples EX2-EX8 were configured such that a charge control layer CCL made of charge control spots CSS was applied to the green emission layer GEML having a wider area starting from the interface between the red emission layer REML and the green emission layer GEML.

In the second to eighth experimental examples EX2-EX8, to examine the effect of uniform island arrangement of the charge control spots CCS in the charge control layer CCL, the thickness of each charge control layer CCL was set to 30 Å, and the overall thickness of the phosphorescent emission layers A was maintained at 50 nm including the red emission layer REML and the green emission layer GEML (red emission layer: 150 Å, green emission layer: 350 Å).

As shown in Table 3 and FIG. 7, in the second to fourth experimental examples EX2, EX3, EX4, as the charge control layer CCL1, CCL3_1, CCL3_2 approached the interface between the red emission layer REML and the green emission layer GEML, accumulation of excitons at the interface between the red emission layer REML and the green emission layer GEML was resolved, light emission distribution was expanded, and external quantum efficiency (EQE) tended to increase, and also operating voltage was slightly lowered. In the fifth experimental example EX5, electron injection capability at the interface between the green emission layer GEML and the electron transport layer ETL was improved, confirming a decrease in operating voltage and an increase in external quantum efficiency (EQE) due to an increased amount of charges in the emission layer. In addition, in all of the second to fifth experimental examples EX2-EX5, distribution of excitons in the emission layer was expanded, and deterioration of excitons was reduced, confirming improved lifespan compared to the first experimental example EX1 (without any charge control layer).

The sixth to eighth experimental examples EX6-EX8 attempted to maximize light emission distribution by introducing a plurality of charge control layers. Referring to Table 4 and FIG. 8, as the number of charge control layers (CCL1+CCL2/CCL1+CCL3_1+CCL2) increased in the sixth and seventh experimental examples EX6, EX7, exciton distribution in the emission layer became wider, and thus, deterioration of excitons was reduced and lifespan was improved compared to the first experimental example EX1 (without any charge control layer). However, as in the eighth experimental example EX8, when four charge control layers (CCL1+CCL3_1+CCL3_2+CCL2) were introduced, lifespan was reduced. In the eighth experimental example EX8, lifespan appears to be reduced as the holes injected into the emission layer move up to the interface of the electron transport layer or electron injection layer due to high hole injection characteristics of the charge control spots, and the ratio of the thickness of the materials (hole transport host, electron transport host, and green dopant) for pure light emission to the thickness of the charge control layer CCL is about 3:1 in the green emission layer GEML, and thus external quantum efficiency (EQE) appears to be lowered with a decrease in the thickness occupied by the materials for pure light emission.

Reviewing the above experiment, when two or less charge control layers using the charge control spots were introduced between the interface of the stacked phosphorescent emission layers and the adjacent electron transport layer, there was an improvement in device performance, and device performance was improved when the charge control layer was applied at a thickness corresponding to less than 20% of the thickness of the thickest phosphorescent emission layer in the phosphorescent emission layers A.

Below is a description of significance of the thickness of the charge control layer through the second experiment.

### Second Experiment

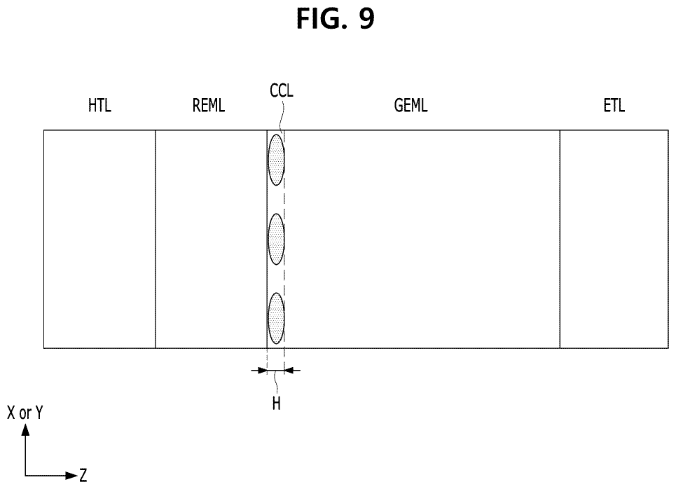

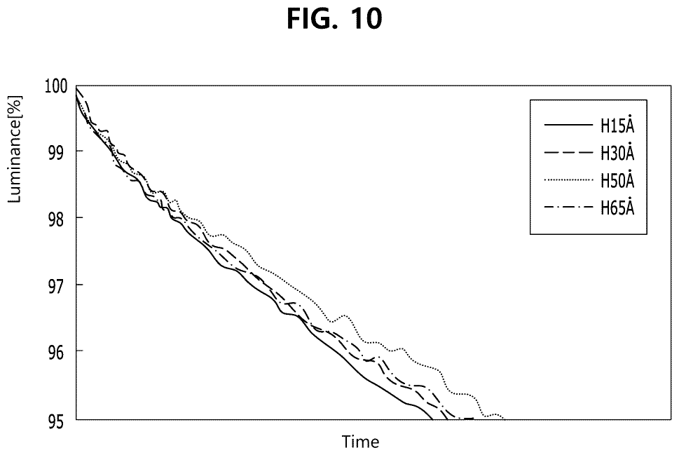

FIG. 9 shows a phosphorescent stack used in the second experiment. FIG. 10 is a graph showing a change in luminance over time depending on the thickness of the charge control layer.

In the second experiment, as shown in FIG. 9, the second experimental modification examples EX2a, EX2b, EX2c were configured such that the charge control layer CCL was disposed at the interface between the red emission layer REML and the green emission layer GEML as in the second experimental example EX2, with the exception that the thickness (H) thereof was changed to 15 Å, 50 Å, and 65 Å.

TABLE 5

| | | Operating | | | |
|---|---|---|---|---|---|
| | H | voltage [V] | Efficiency | EQE | Lifespan |
| Classification | [Å] | (at 10J) | (Cd/A, %) | (%) | (T95, %) |
| EX1 | 0 | 4.0 | 100 | 1006 | 100 |
| EX2 | 30 | 3.9 | 107 | 107 | 107 |
| EX2a | 15 | 4.0 | 99 | 99 | 98 |
| EX2b | 50 | 4.0 | 93 | 96 | 125 |
| EX2c | 65 | 4.0 | 92 | 95 | 109 |

Referring to Table 5 and FIG. 10, when the thickness of the charge control layer CCL was 15 Å (EX2a), luminance, external quantum efficiency, and lifespan in the green emission layer GEML were similar to those of the first experimental example EX1. This is deemed to be because the charge control layer CCL is too thin to exhibit uniform characteristics in the green emission layer GEML.

When the thickness (H) of the charge control layer CCL was set to 30 Å (EX2), 50 Å (EX2b), and 65 Å (EX2c), greater than 15 Å, lifespan (T95) was improved compared to the first experimental example EX1. However, when the thickness (H) of the charge control layer CCL was equal to or greater than 50 Å (EX2b), external quantum efficiency (EQE) decreased, which is deemed to be because the charge control layer CCL plays a role similar to a separation layer when distributed thickly in the green emission layer GEML, limiting the expansion of light emission distribution.

Therefore, in aspects of the present disclosure, the thickness of the charge control layer CCL provided in the green emission layer GEML is set to 15 Å to 65 Å in consideration of lifespan characteristics. More particularly, in aspects of the present disclosure, the thickness of the charge control layer CCL provided in the green emission layer GEML may fall in the range of 30 Å to 50 Å considering efficiency, operating voltage, lifespan, etc.

Below is a description of significance of application of charge control spots CCS to the green emission layer GEML in the light emitting device according to the aspect described above.

When the charge control spots are applied to the red emission layer having the properties shown in Table 2, hole transport of the charge control spots CCS is slower than the hole transport layer HTL and the hole transport host RHH of the red emission layer REML, so operating voltage may rise. Additionally, since the charge control spots are a bipolar material with strong electron transport characteristics, there is a possibility that excitons may leak into the hole transport layer HTL.

In contrast, as in the fifth experimental example EX5, when a charge control layer CCL including charge control spots CCS is provided at the interface between the green emission layer GEML and the electron transport layer ETL, charges lost due to low triplet energy level (T1) of the material for the electron transport layer ETL may be injected into the green emission layer GEML through the charge control layer CCL. Therefore, when a charge control layer CCL including charge control spots CCS is provided in the green emission layer GEML, external quantum efficiency (EQE) increases due to an increase in the number of charges participating in light emission, and lifespan is improved.

By controlling the internal charges of a relatively thick phosphorescent emission layer in a structure in which a plurality of phosphorescent emission layers A is stacked, the light emitting device according to an aspect of the present disclosure is capable of preventing charge loss through expansion of exciton distribution and preventing excitons from accumulating at the interface of the emission layers, thereby improving both device efficiency and lifespan.

The second to eighth experimental examples showed application of the charge control spots CCS to the green emission layer GEML in a stack of the red emission layer REML and the green emission layer GEML, and the effect thereof was confirmed, but the aspect of the present disclosure is not limited thereto. In a structure with a plurality of phosphorescent emission layers A, interlayer distribution of the charge control spots is possible in the form of islands, and the charge control spots have bipolar properties with strong hole transport and strong electron transport, making it possible to control energy transfer to a phosphorescent dopant and exciton flow in the phosphorescent emission layer provided therewith. Also, the charge control spots may be applied to emission layers of wavelengths other than green so long as they do not form an exciplex with the adjacent common layer.

Below is a description of application of the light emitting device to a light emitting display device.

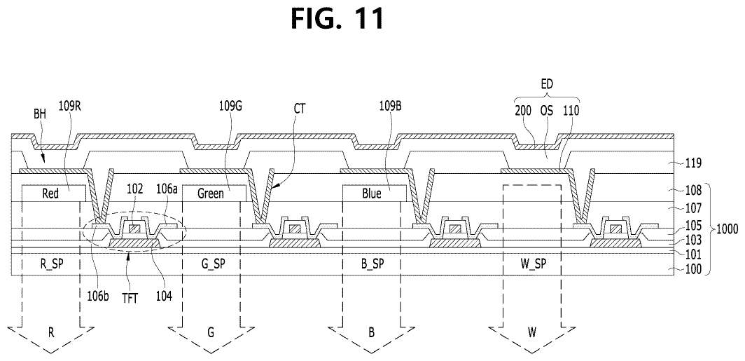

FIG. 11 is a cross-sectional view showing a light emitting display device according to an aspect of the present disclosure.

As shown in FIG. 11, the light emitting display device according to an aspect of the present disclosure is capable of emitting white light through the first electrode 110 at the emission side by applying the light emitting device commonly to a plurality of sub-pixels R_SP, G_SP, B_SP, W_SP.

As shown in FIG. 11, the light emitting display device according to an aspect of the present disclosure includes a substrate 100 having a plurality of sub-pixels R_SP, G_SP, B_SP, W_SP, a light emitting device ED commonly provided on the substrate 100, a thin film transistor TFT provided in each of the sub-pixels R_SP, G_SP, B_SP, W_SP and connected to the first electrode 110 of the light emitting device ED, and color filter layers 109R, 109G, 109B provided under the first electrode 110 in at least one of the sub-pixels.

The light emitting display device including the white sub-pixel W_SP is illustrated in FIG. 11, but the present disclosure is not limited thereto, and a configuration in which the white sub-pixel W_SP is omitted and only the red, green, and blue sub-pixels R_SP, G_SP, B_SP are provided is also possible. In some cases, a combination of a cyan sub-pixel, a magenta sub-pixel, and a yellow sub-pixel capable of representing white may be used, in lieu of the red, green, and blue sub-pixels.

The thin film transistor TFT includes, for example, a gate electrode 102, a semiconductor layer 104, and a source electrode 106a and a drain electrode 106b connected to both sides of the semiconductor layer 104. Additionally, a channel passivation layer may be further provided on the semiconductor layer 104 in which the channel is located, to prevent direct connection between the source/drain electrodes 106a, 106b and the semiconductor layer 104. A buffer layer 101 may be provided on the substrate 100, and the thin film transistor TFT may be disposed on the buffer layer 101.

A gate insulating film 103 is provided between the gate electrode 102 and the semiconductor layer 104.

The semiconductor layer 104 may be formed of, for example, any one or a combination of two or more among an oxide semiconductor, amorphous silicon, and polycrystalline silicon. For example, when the semiconductor layer 104 is an oxide semiconductor, the heating temperature required to form a thin film transistor may be lowered, and thus the substrate 100 has a high degree of freedom in use, so application to a flexible display device may become advantageous.

The gate electrode 102 may be provided on the gate insulating film 103, and an interlayer insulating film 105 may be further provided between the gate electrode 102 and the source electrode 106a/drain electrode 106b.

Moreover, the drain electrode 106b of the thin film transistor TFT may be connected to the first electrode 110 in the region of a contact hole CT provided in first and second passivation films 107, 108.

The first passivation film 107 is provided primarily to protect the thin film transistor TFT, and color filters 109R, 109G, 109B may be provided on the first passivation film 107.

The second passivation film 108 may be provided on the first passivation film 107 including the color filters 109R, 109G, 109B.

As shown in FIG. 11, when the sub-pixels include a red sub-pixel R_SP, a green sub-pixel G_SP, a blue sub-pixel B_SP, and a white sub-pixel W_SP, first to third color filters 109R, 109G, 109B may be provided to respective sub-pixels R_SP, G_SP, B_SP other than the white sub-pixel W_SP, allowing white light emitted through the first electrode 110 to pass at each wavelength. The second passivation film 108 is configured to cover the first to third color filters 109R, 109G, 109B and formed under the first electrode 110. The first electrode 110 is formed on the surface of the second passivation film 108 excluding the contact hole CT and is connected to either the drain electrode 106b or the source electrode 106a of the thin film transistor TFT, receiving an electrical signal by the thin film transistor TFT.

Here, a structure including the substrate 100, the thin film transistor TFT, the color filters 109R, 109G, 109B, and the first and second passivation films 107, 108 may be referred to as a thin film transistor array substrate 1000.

The light emitting device ED is formed on the thin film transistor array substrate 1000 including a bank 119 defining a light emitting portion BH. The light emitting device ED may include a transparent first electrode 110 and a reflective second electrode 300 facing the same, and may sequentially include a hole transport layer HTL, an electron blocking layer EBL, a blue emission layer BEML including a host BH and a blue dopant BD, and an electron transport layer ETL, in at least one of the first blue stack B1 or the second blue stack B2 among stacks divided by the first and second charge generation layers CGL1, CGL2, as described above, between the first electrode 110 and the second electrode 200.

The first electrode 110 may be provided dividedly for each sub-pixel, and the remaining layers except for the first electrode 110 of the light emitting device ED may be provided integrally throughout the active area without separate division for each sub-pixel.

Either the first electrode 110 or the second electrode 200 may be connected to the thin film transistor TFT.

In the light emitting display device according to an aspect of the present disclosure described above, when the internal efficiency of the phosphorescent emission layer and lifespan are improved by providing a charge control layer in which charge control spots are distributed in the relatively thick phosphorescent emission layer described in FIGS. 1 to 3, the light emitting device ED that emits white light makes it possible to maintain the luminous efficacy balance with the phosphorescent stack, greatly contributing to lowering power consumption and realizing high luminance and long lifespan.

In the light emitting device according to an aspect of the present disclosure and the light emitting display device including the same, charge control spots are distributed in at least one of a plurality of phosphorescent emission layers in a phosphorescent stack in which the phosphorescent emission layers are continuously disposed, thus increasing the amount of charges and controlling the flow of charges, thereby improving luminous efficacy. In addition, the host and the charge control spots are provided in the same plane in the emission layer, thus preventing charges from accumulating at the interface of the emission layers, ultimately improving lifespan.

The light emitting device according to the present disclosure and the light emitting display device including the same may improve luminous efficacy by changing the internal material of the emission layer and may also increase luminance, making it possible to lower power consumption, thus reducing environmental pollution and sustaining long lifespan characteristics, thereby realizing ESG (environment/social/governance) characteristics.

A light emitting device according to one aspect of the present disclosure may comprise a first electrode and a second electrode facing each other and an intermediate layer structure having at least one blue stack and at least one phosphorescent stack between the first electrode and the second electrode. The at least one phosphorescent stack may comprise a first phosphorescent emission layer and a second phosphorescent emission layer in contact with each other between a hole transport layer and an electron transport layer, and at least one of the first phosphorescent emission layer or the second phosphorescent emission layer may comprise charge control spots dispersed in a host.

In a light emitting device according to one aspect of the present disclosure, the charge control spots may comprise a plurality of plate-like structures, the second phosphorescent emission layer may be thicker than the first phosphorescent emission layer, and the plurality of plate-like structures may be provided in the second phosphorescent emission layer.

In a light emitting device according to one aspect of the present disclosure, the plurality of plate-like structures may be provided as a plurality of layers spaced apart from each other in a perpendicular direction in the second phosphorescent emission layer.

In a light emitting device according to one aspect of the present disclosure, the charge control spots may comprise a plurality of plate-like structures, and the plurality of plate-like structures may be arranged parallel to an interface between the first phosphorescent emission layer and the second phosphorescent emission layer. The host may be filled among the plurality of plate-like structures.

In a light emitting device according to one aspect of the present disclosure, the charge control spots may comprise at least one of a first charge control layer provided in contact with the interface between the first phosphorescent emission layer and the second phosphorescent emission layer, a second charge control layer provided in contact with an interface between the second phosphorescent emission layer and the electron transport layer and a third charge control layer provided in the second phosphorescent emission layer while being spaced apart from the interface between the first phosphorescent emission layer and the second phosphorescent emission layer, and provided parallel to the interface between the first phosphorescent emission layer and the second phosphorescent emission layer.

In a light emitting device according to one aspect of the present disclosure, a plurality of third charge control layers may be provided at different vertical distances from the interface between the first phosphorescent emission layer and the second phosphorescent emission layer.

In a light emitting device according to one aspect of the present disclosure, a first vertical distance of the third charge control layer from the interface between the first phosphorescent emission layer and the second phosphorescent emission layer may be less than a second vertical distance between the third charge control layer and the electron transport layer.

In a light emitting device according to one aspect of the present disclosure, at least one of the first charge control layer, the second charge control layer, and the third charge control layer may have a thickness of 15 Å to 65 Å.

In a light emitting device according to one aspect of the present disclosure, the charge control spots may have a triplet energy level greater than a triplet energy level of a dopant of the second phosphorescent emission layer.

In a light emitting device according to one aspect of the present disclosure, the charge control spots may be an organic material containing both a hole transport group and an electron transport group.

In a light emitting device according to one aspect of the present disclosure, the charge control spots may contain an indolocarbazole group and a triazine group.

In a light emitting device according to one aspect of the present disclosure, the host may comprise a hole transport host and an electron transport host, and the charge control spots may have a HOMO energy level lower than a HOMO energy level of the hole transport host.

In a light emitting device according to one aspect of the present disclosure, the second phosphorescent emission layer may be a green emission layer, and the first phosphorescent emission layer may be an emission layer configured to emit light of a longer wavelength than green.

A light emitting device according to one aspect of the present disclosure, may further comprise a third phosphorescent emission layer on one surface of the first phosphorescent emission layer that is not in contact with the second phosphorescent emission layer.

A light emitting device according to one aspect of the present disclosure may further comprise a charge generation layer between the at least one blue stack and the at least one phosphorescent stack.

A light emitting display device according to one aspect of the present disclosure may comprise a substrate comprising a plurality of sub-pixels, a thin film transistor provided in each of the plurality of sub-pixels and a light emitting device connected to the thin film transistor in each of the plurality of sub-pixels. The light emitting device may comprise an intermediate layer structure having at least one blue stack and at least one phosphorescent stack between a first electrode and a second electrode. The at least one phosphorescent stack may comprise a first phosphorescent emission layer and a second phosphorescent emission layer in contact with each other between a hole transport layer and an electron transport layer. At least one of the first phosphorescent emission layer or the second phosphorescent emission layer may comprise charge control spots dispersed in a host.

A light emitting display device according to one aspect of the present disclosure may further comprise a color filter, as any one layer between the substrate and the light emitting device, in at least one of the plurality of sub-pixels.

As is apparent from the above description, a light emitting device according to the present disclosure and a light emitting display device including the same have the following effects.

Charge control spots are distributed in at least one of a plurality of phosphorescent emission layers in a phosphorescent stack in which the phosphorescent emission layers are continuously disposed, thus increasing the amount of charges and controlling the flow of charges, thereby improving luminous efficacy. Moreover, a host and charge control spots are provided in the same plane in the emission layer, thus preventing charges from accumulating at the interface of the emission layers, ultimately improving lifespan.

The light emitting device according to the present disclosure and the light emitting display device including the same may improve luminous efficacy by changing the internal material of the emission layer and may also increase luminance, making it possible to lower power consumption, thus reducing environmental pollution and sustaining long lifespan characteristics, thereby realizing ESG (environment/social/governance) characteristics.

It will be apparent to those skilled in the art that various modifications and variations can be made in the light emitting device and the light emitting display device of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A light emitting device, comprising:
a first electrode and a second electrode facing each other; and
an intermediate layer structure having at least one blue stack and at least one phosphorescent stack disposed between the first electrode and the second electrode,
wherein the at least one phosphorescent stack includes a first phosphorescent emission layer and a second phosphorescent emission layer in contact with each other between a hole transport layer and an electron transport layer, and
wherein at least one of the first phosphorescent emission layer and the second phosphorescent emission layer includes charge control spots.

2. The light emitting device according to claim 1, wherein the charge control spots includes a plurality of plate-like structures,
wherein the second phosphorescent emission layer is thicker than the first phosphorescent emission layer, and
wherein the plurality of plate-like structures is disposed in the second phosphorescent emission layer.

3. The light emitting device according to claim 2, wherein the plurality of plate-like structures is provided as a plurality of layers spaced apart from one another in a perpendicular direction in the second phosphorescent emission layer.

4. The light emitting device according to claim 2, wherein the charge control spots comprise a plurality of plate-like structures, and
wherein the plurality of plate-like structures is arranged parallel to an interface between the first phosphorescent emission layer and the second phosphorescent emission layer.

5. The light emitting device according to claim 4, wherein the charge control spots includes a first charge control layer adjacent to the interface between the first phosphorescent emission layer and the second phosphorescent emission layer and a second charge control layer adjacent to an interface between the second phosphorescent emission layer and the electron transport layer.

6. The light emitting device according to claim 4, wherein the charge control spots includes at least one third charge control layer adjacent to the interface between the first phosphorescent emission layer and the second phosphorescent emission layer.

7. The light emitting device according to claim 4, wherein the charge control spots constitute at least one of:
a first charge control layer provided in contact with the interface between the first phosphorescent emission layer and the second phosphorescent emission layer;
a second charge control layer provided in contact with an interface between the second phosphorescent emission layer and the electron transport layer; and
at least one third charge control layer provided in the second phosphorescent emission layer while being spaced apart from the interface between the first phosphorescent emission layer and the second phosphorescent emission layer, and provided parallel to the interface between the first phosphorescent emission layer and the second phosphorescent emission layer.

8. The light emitting device according to claim 6, wherein the at least one third charge control layer includes a plurality of third charge control layer provided at different vertical distances from the interface between the first phosphorescent emission layer and the second phosphorescent emission layer.

9. The light emitting device according to claim 8, wherein the different vertical distances include a first vertical distance of the third charge control layer from the interface between the first phosphorescent emission layer and the second phosphorescent emission layer that is less than a second vertical distance between the third charge control layer and the electron transport layer.

10. The light emitting device according to claim 6, wherein at least one of the first charge control layer, the second charge control layer, and the at least one third charge control layer has a thickness of 15 Å to 65 Å.

11. The light emitting device according to claim 2, wherein the charge control spots have a triplet energy level greater than a triplet energy level of a dopant of the second phosphorescent emission layer.

12. The light emitting device according to claim 1, wherein the charge control spots include an organic material containing both a hole transport group and an electron transport group.

13. The light emitting device according to claim 1, wherein the charge control spots contain an indolocarbazole group and a triazine group.

14. The light emitting device according to claim 1, wherein the host comprises a hole transport host and an electron transport host, and
wherein the charge control spots have a HOMO energy level lower than a HOMO energy level of the hole transport host.

15. The light emitting device according to claim 2, wherein the second phosphorescent emission layer is a green emission layer, and
wherein the first phosphorescent emission layer is an emission layer configured to emit light of a longer wavelength than green.

16. The light emitting device according to claim 15, further comprising a third phosphorescent emission layer disposed on one surface of the first phosphorescent emission layer that is not in contact with the second phosphorescent emission layer.

17. The light emitting device according to claim 1, further comprising a charge generation layer between the at least one blue stack and the at least one phosphorescent stack.

18. A light emitting display device, comprising:
a substrate comprising a plurality of sub-pixels;
a thin film transistor provided in each of the plurality of sub-pixels; and
a light emitting device connected to the thin film transistor in each of the plurality of sub-pixels, the light emitting device comprising an intermediate layer structure having at least one blue stack and at least one phosphorescent stack between a first electrode and a second electrode,
wherein the at least one phosphorescent stack comprises a first phosphorescent emission layer and a second phosphorescent emission layer in contact with each other between a hole transport layer and an electron transport layer,
at least one of the first phosphorescent emission layer and the second phosphorescent emission layer comprises charge control spots.

19. The light emitting display device according to claim 18, further comprising a color filter disposed between the substrate and the light emitting device in at least one of the plurality of sub-pixels.
